(19) United States
(12) Patent Application Publication
(10) Pub. No.: US 2006/0197112 A1
(43) Pub. Date: Sep. 7, 2006

(54) Optical Coupling Device

(75) Inventors: Takeshi Uchihara, Tokyo (JP); Yasunori Usui, Tokyo (JP); Takashi Nishimura, Tokyo (JP)

Correspondence Address: BANNER & WITCOFF, LTD., ATTORNEYS FOR RESERVE;ATTORNEYS FOR CLIENT NO. 000449, 001701, 1001 G STREET, N.W., 11TH FLOOR, WASHINGTON, DC, 20001-4597, US

(73) Assignee: KABUSHIKI KAISHA TOSHIBA, Tokyo (JP)

(21) Appl. No.: 11/275,020

(22) Filed: Dec. 2, 2005

(30) Foreign Application Priority Data
Dec. 2, 2004 (JP) 2004-349426
Nov. 30, 2005 (JP) 2005-346952

(51) Int. Cl. H01L 29/76

(52) U.S. Cl. 257/213

(57) ABSTRACT

In various aspects, an optical coupling device may include a light emitting element configured to emit an optical signal; a photo receiving element having a serial connected of photo diodes, the photo receiving element configured to receive the optical signal and generate an electrical signal; and a control circuit having an active element, a source and a drain of the active element connected to both ends of the photo receiving element; wherein the breakdown voltage of the control circuit is no more than an open circuit voltage of the photo receiving element.

### CROSS REFERENCE TO RELATED APPLICATION

This application is based upon and claims the benefit of priority from Japanese Patent Application No. 2004-349426, filed on Dec. 2, 2004, and Japanese Patent Application No. 2005-346952, filed on Nov. 30, 2005, the entire contents of which are incorporated herein by reference.

### BACKGROUND OF THE INVENTION

A photo relay, which has an LED (light emitting device), a photo receiving element, a control circuit and an output MOSFET, is known as an optical coupling device.

Increasing a gate driving voltage of an output MOSFET is required in order to reduce ON-resistance (Ron). If a number of photo receiving elements (arranged serially) is increased, the gate driving voltage is increased and Voc (Voltage of Open Circuit) is increased.

There is another requirement for increasing Voc of photo coupler which has a LED, a photo receiving element and a control circuit.

However, in the conventional optical coupling device, an output voltage Voc is changed depending on a driving current of the LED (or I_{F}). A breakdown voltage between Gate and Source of MOSFET (Vgs) is unnecessarily set to a high voltage in order to solve that problem. The high breakdown voltage prevents the Ron from being reduced.

### SUMMARY

In one aspect of the present invention, an optical coupling device may include a light emitting element configured to emit an optical signal; a photo receiving element having a serial connected of photo diodes, the photo receiving element configured to receive the optical signal and generate an electrical signal; and a control circuit having an active element, a source and a drain of the active element connected to both ends of the photo receiving element, wherein the breakdown voltage of the control circuit is no more than an open circuit voltage of the photo receiving element.

In another aspect of the invention, an optical coupling device may include a light emitting element configured to emit an optical signal; a photo receiving element having a serial connected of photo diodes, the photo receiving element configured to receive the optical signal and generate an electrical signal; and an active element connected to the photo receiving element, a source and a drain of the active element connected to both ends of the photo receiving element, wherein the breakdown voltage of the active element is no more than an open circuit voltage of the photo receiving element.

### BRIEF DESCRIPTIONS OF THE DRAWINGS

FIG. 1 is a circuit diagram of a photo coupler as an optical coupling device in accordance with a first and a second embodiment of the present invention.

FIG. 2 is a circuit diagram of photo relay as an optical coupling device in accordance with a first and a second embodiment of the present invention.

FIG. 3 is a graph showing a relationship between an open circuit voltage of a photo receiving element Vocpd1, an open circuit voltage of photo coupler Voc and a breakdown voltage of MOSFET Vdss (MOS-Vdss).

FIG. 4 is a circuit diagram of a photo coupler as an optical coupling device in accordance with a third embodiment of the present invention.

FIG. 5 is a circuit diagram of a photo relay as an optical coupling device in accordance with a third embodiment of the present invention.

FIG. 6 is a characteristic diagram showing an output voltage of photodiode and driving current of LED.

FIG. 7 is a circuit diagram of a photo coupler as an optical coupling device in accordance with a fourth embodiment of the present invention.

FIG. 8 is a circuit diagram of a photo relay as an optical coupling device in accordance with a fourth embodiment of the present invention.

### DETAILED DESCRIPTION OF THE INVENTION

Various connections between elements are hereinafter described. It is noted that these connections are illustrated in general and, unless specified otherwise, may be direct or indirect and that this specification is not intended to be limiting in this respect.

Embodiments of the present invention will be explained with reference to the drawings as follows.

### First Embodiment

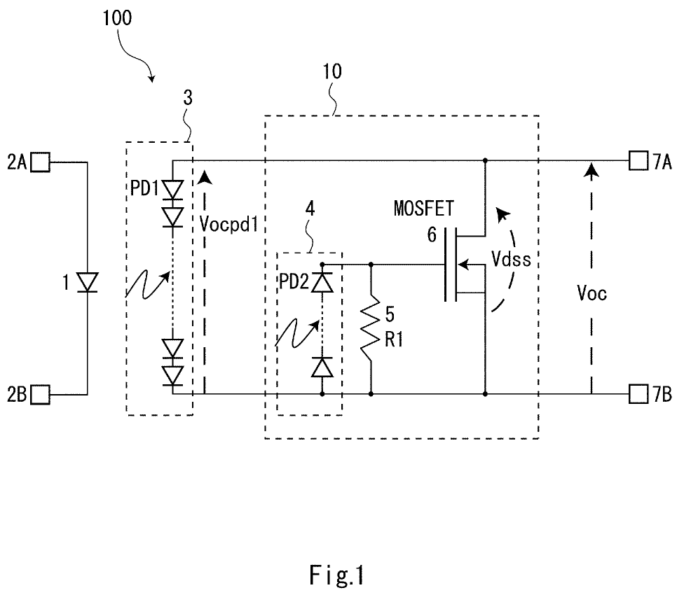

A first embodiment of the present invention will be explained hereinafter with reference to FIG. 1 to FIG. 3 and FIG. 6.

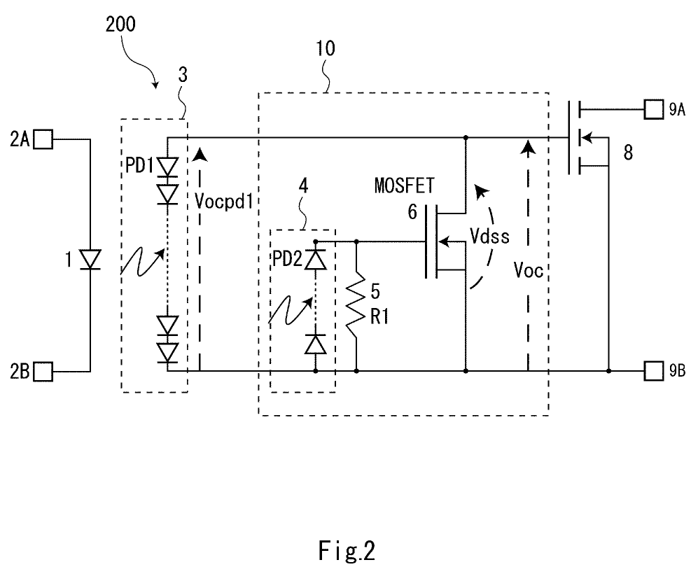

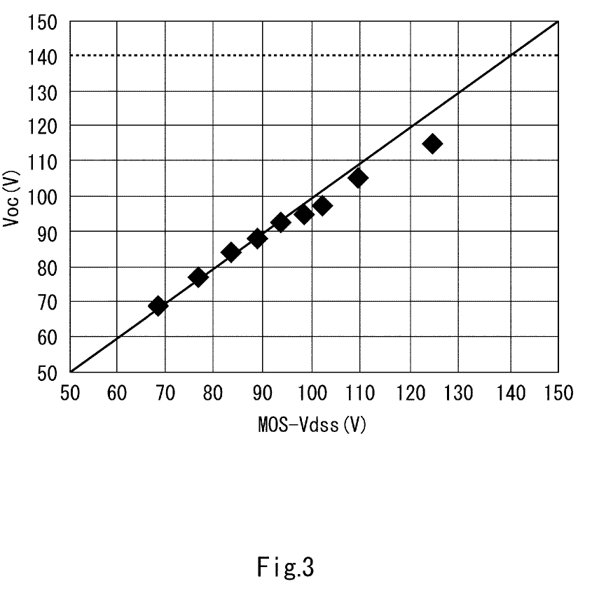

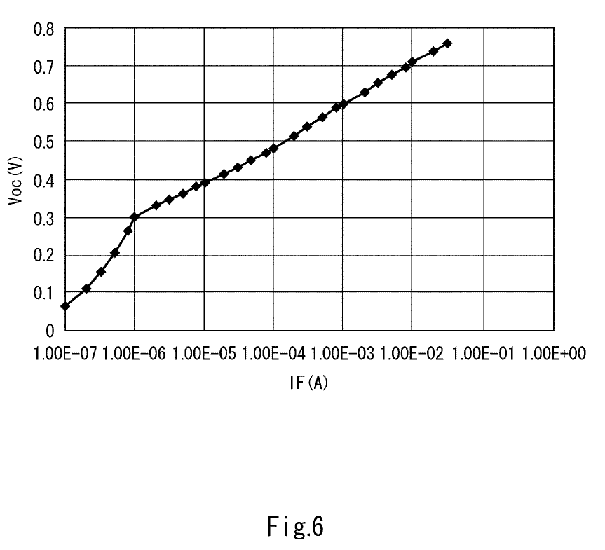

FIG. 1 is a circuit diagram of a photo coupler as an optical coupling device in accordance with a first embodiment of the present invention. FIG. 2 is a circuit diagram of photo relay as an optical coupling device in accordance with a first embodiment of the present invention. FIG. 3 is a graph showing a relationship between an output voltage of a photo receiving element Vocpd1, an output voltage of photo coupler Voc and a breakdown voltage of MOSFET Vdss (MOS-Vdss). FIG. 6 is a characteristic diagram showing an output voltage of photodiode and driving current of LED.

A structure of an optical coupling device of the first embodiment will be explained by a photo coupler 100 with reference to FIG. 1 and by a photo relay 200 with reference to FIG. 2.

As shown in FIG. 1, the photo coupler 100 has a LED 1, which emits a light signal corresponding to an input electrical signal, a first photo receiving element 3, which is composed of a plurality of serially connected photodiodes PD1, and a control circuit 10 connected to the photo receiving element 3. The photodiodes PD1 are configured to receive output (light) from the LED 1 and generate electrical power.

An anode of the LED 1 is connected to an input terminal 2A and a cathode of the LED 1 is connected to an input terminal 2B. Light emitted from the LED 1 is received by the first photo receiving element 3 and a second photo receiving element 4 of the control circuit 10. A light emitting element 1 may be one or more LEDs, one or more LDs (Laser Diodes), a combination of LEDs and LDs, or other light emitting/generating devices.

The control circuit 10 has a MOSFET 6 and a resistance element 5 and the second photo receiving element 4.

The second photo receiving element 4 may include a serial array of a plurality of photodiodes PD2 that receives light and generates electric power. The second photo receiving element 4 receives light from LED 1 and controls a high or low impedance between a drain and source of the MOSFET 6 in accordance with the light signal. As shown in FIG. 1, MOSFET 6 is a normally ON type N type MOSFET. The MOSFET 6 is turned off when light is received by the second photo receiving element 4, and the impedance of the control circuit 10 is high. The MOSFET 6 is turned on when light is not input to the second photo receiving element 4, and the impedance of the control circuit 10 is low.

The MOSFET 6 is connected in parallel with the first photo receiving element 3. The second photo receiving element 4 may be connected to the source and the gate of the MOSFET 6. A cathode of the second photo receiving element 4 may be connected to the gate of the MOSFET 6. An anode of the second photo receiving element 4 may be connected to the source of the MOSFET 6 and an anode of the first photo receiving element 3. The resistance element (R1) 5 may be connected parallel to the second photo receiving element 4.

A drain of the MOSFET 6 may be connected to an output terminal 7A and a source of the MOSFET 6 may be connected to output terminal 7B.

In this first embodiment, an open circuit voltage (Vocpd1) of the first photo receiving element 1 may be equal to or higher than the breakdown voltage (Vdss) of the MOSFET 6 of the control circuit 10 (that is Vocpd1≦Vdss). In other words, the breakdown voltage Vdss is no more than the open circuit voltage Vocpd1 of the first photo receiving element 1.

In this first embodiment, if the output voltage of the first photo receiving element 3 is changed, an output voltage of the optical coupling device is stable. One reason is that the Voc is dependent on the breakdown voltage, Vdss of the MOSFET 6. The reason is explained more detailed hereinafter.

(1) In case Vocpd1<Vdss.

In this case, the open circuit voltage Vocpd1 of the first photo receiving element 3 is less than the breakdown voltage Vdss between the source and the drain of the MOSFET 6, and the MOSFET 6 is in an OFF state. So, the open circuit voltage Vocpd1 of the first photo receiving element 3 is output at the output terminals 7A, 7B.

(2) In case Vocpd1≧Vdss.

In this case, the open circuit voltage Vocpd1 of the first photo receiving element 3 is equal to or higher than the breakdown voltage Vdss between the source and the drain of the MOSFET 6. Accordingly, a current between the source and the drain of the MOSFET 6 is shown, before Vocpd1 is equal to Vdss. Namely, when Vocpd1 is higher than Vdss, the output voltage is Vdss and output at terminal 7A.

In this embodiment, the breakdown voltage of the control circuit is no more than the open circuit voltage of the photo receiving element. A stable output voltage can be obtained in the optical coupling device.

A structure of the photo relay 200 is explained hereinafter with reference to FIG. 2. A difference between the photo coupler 100 as shown in FIG. 1 and the photo relay 200 as shown in FIG. 2 is the inclusion of an output MOSFET 8.

A gate of the output MOSFET 8 is connected to the anode of the first photo receiving element 3 and the drain of the MOSFET 6. A source of the output MOSFET 8 is connected to the cathode of the first photo receiving element 3, the anode of the second photo receiving element 4, and the source of the MOSFET 6.

When the output voltage Voc that is controlled by the control circuit 10 is added to the gate and the drain of the output MOSFET 8, the gate and the source are charged and the impedance is changed from high to low. Accordingly, a signal is output at an output terminal 9A and 9B.

In the photo relay 200 shown in FIG. 2, the breakdown voltage Vdss of the MOSFET 6 as an active element of the control circuit 10 is no more than the open circuit voltage of the photo receiving element. A stable output voltage can be obtained in the optical coupling device.

As mentioned above, the breakdown voltage of the control circuit is no more than the open circuit voltage of the photo receiving element.

A characteristic of a photodiode array of a conventional optical coupling device is explained for assisting with the explanation of the first embodiment.

Generally, an open circuit optical voltage of a photodiode is shown a (formula 1).
Vocpd=(kB*T/q)ln (1+(JL/JS)) (formula 1)

kB: Boltzmann constant. q: charge of electron. JL: short circuit current density. JS: reverse saturation current density.

The JL of photodiode (PD) is proportional with the quantity of light emitted from the LED. As the quantity of light is increased, the open circuit voltage Voc is increases as shown in formula 1. However, in one pn junction, an output is saturated about 0.7 V (in Si) which is corresponding to a built-in potential of the pn junction.

A high open circuit voltage Vocpd can be obtained by using a photodiode array which may include serially connected plurality of photodiodes. The open circuit voltage is represented as (formula 2).
Vocpd=(kB*T/q)ln (1+(JL/JS))*n (formula 2)

n: a number of serial connected photodiodes.

A high open circuit voltage Vocpd can be obtained by photodiode array. However, the output voltage is changed primarily depending on the quantity of light. For example, in case the LED driving current I_{F} is 1 mA and an output of the photodiode array having 14 photodiodes is about 8.3 V, the open circuit voltage Vocpd is about 10 V by adding the LED current I_{F} 10 mA. This is because an output power of each photodiodes is saturated.

If the open circuit voltage Vocpd is 80 V by using the photodiode array, 135 photodiodes are needed (80V/(8.3V/14 photodiodes)=134.9 photodiodes). An open circuit voltage Vocpd is (10V/14 photodiodes)*135 photodiodes=96.4 V when the LED driving current I_{F} is increased up to 10 mA.

The open circuit voltage Vocpd is 80V when the I_{F} is 1 mA. However, the open circuit voltage Vocpd is 96 V when the I_{F} is 10 mA and the output voltage is increased largely depending on the LED driving current I_{F}.

It may be necessary in the conventional optical coupling device that the breakdown voltage Vgs between the gate and the source is set to an unnecessarily high voltage. Accordingly, it is hard to reduce the ON-resistance in the conventional optical coupling device because of the breakdown volage Vgs is set high.

As comparing to the conventional optical coupling device, in the optical coupling device of the first embodiment, the breakdown voltage between the source and the drain is no more than the open circuit voltage of the photo receiving element. Accordingly, a change of the Voc depending on a change of I_{F} is reduced.

A relationship between the breakdown voltage of the control circuit and the open circuit voltage of the photodiode array will be explained hereinafter.

In this first embodiment, a relationship between open circuit voltage Vocpd1 of the first photo receiving element 3 and the source-drain breakdown voltage Vdss (or avalanche voltage) is represented (Formula 3).
Vocpd1≧Vdss (Formula 3)

In this embodiment, the source-drain breakdown voltage Vdss of the MOSFET is no more than the open circuit voltage Vocpd1 of the photo receiving element. A stable output voltage can be obtained in the optical coupling device.

The source-drain breakdown voltage Vdss of the MOSFET 6 and measurement are explained.

In FIG. 3, a horizontal axis shows an output voltage Voc (V) of the optical coupling device, and a vertical axis shows a breakdown voltage of MOSFET Vdss (MOS-Vdss) (V). In FIG. 3, the measurement of a sample designed Vocpd1≧Vdss is also shown. The sample is designed so that the open circuit voltage Vocpd1 is 140 V. The output voltage Voc of the optical coupling device is substantially coincident with the breakdown voltage Vdss.

The output voltage Voc is decided by the breakdown voltage Vdss of MOSFET, and a stable output can be obtained.

### Second Embodiment

The second embodiment will be explained with reference to FIGS. 1-3 and FIG. 6.

In this second embodiment, the output voltage of the photo coupler 100 is 80 V.

In the first photo receiving element 3, a number of photodiodes PD1 connected serially is defined n. The n is a positive integer. If the LED is driven 0.5-20 mA in driving current, 0.55-0.75 V can be obtained as an output voltage per one photodiode PD1 and output from the output at terminal 7A, 7B.

The open circuit voltage Vocpd1 of the photodiode array 3 is represented as (Formula 4).
0.55*n≦Vocpd1≦0.75*n (Formula 4)

In this embodiment, the optical coupling device meets (Formula 3). So, (Formula 5) is calculated from (Formula 3) and (Formula 4).
Vdss≦0.55*n (Formula 5)

In this case, as shown in FIG. 3, the breakdown voltage Vdss of the control circuit 10 (that is MOSFET 6) is 80V since the Voc is 80V From (Formula 5), 80V≦0.55*n V.

n≧145.45.

n=146.

Therefore a suitable number of photodiodes of the first photo receiving element 3 is 146 photodiodes. From (Formula 4), the Vocpd1 is

0.55*146≦Vocpd1≦0.75*146

So, 80.3 V≦Vocpd1≦109.5 V

However the breakdown voltage Vdss of the MOSFET 6 is set to 80 V,

Vdss=80 V<80.3 V≦Vocpd1≦109.5 V. The output voltage Voc is constant, 80V.

As shown in FIG. 3, a measurement of sample designed Vocpd1≧Vdss, though the Vocpd1 is designed 140 V, the output voltage Voc is substantially coincident with the Vdss of the MOSFET. Accordingly, a stable output can be obtained, since the output voltage Voc is decided by the Vdss.

### Third Embodiment

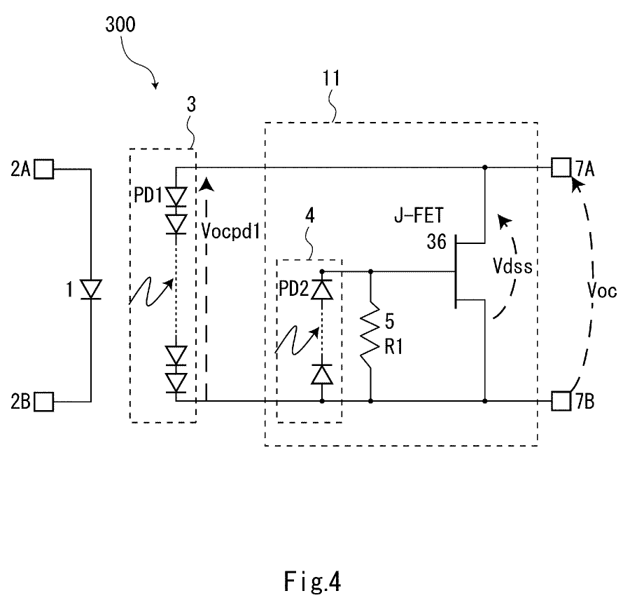

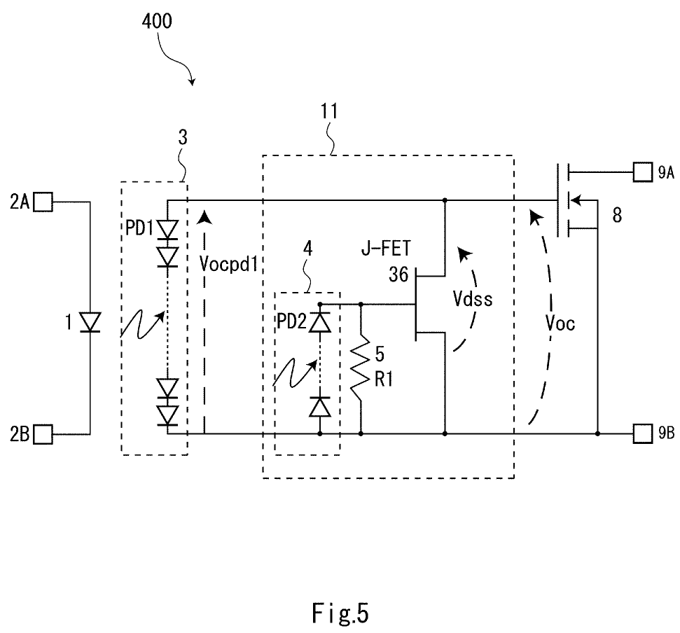

A third embodiment is explained with reference to FIGS. 4 and 5.

An optical coupling device is described in accordance with a third embodiment of the present invention. With respect to each portion of this embodiment, the same or corresponding portions of the optical coupling device of the first or second embodiment shown in FIGS. 1-3 and FIG. 6 are designated by the same reference numerals, and explanation of such portions is omitted.

FIG. 4 is a circuit diagram of a photo coupler as an optical coupling device in accordance with a third embodiment.

A photo coupler 300 is different in active element of control circuit from the photo coupler 100 shown in FIG. 1. The photo coupler 300 has a J-FET 36 as an active element in a control circuit 11.

The open circuit voltage Vocpd1 of the photo receiving element 3 is equal to or higher than a breakdown voltage Vdss of the J-FET 36 of the control circuit 11. In other words, a source-drain breakdown voltage Vdss is no more than the open circuit voltage Vocpd1 of the first photo receiving element 3.

FIG. 5 is a circuit diagram of a photo relay as an optical coupling device in accordance with a third embodiment.

A photo relay 400 is different in active element from the photo relay 200 shown in FIG. 2. The photo relay 400 has a J-FET 36 as an active element in the control circuit 11.

The open circuit voltage Vocpd1 of the photo receiving element 3 is equal to or higher than a breakdown voltage Vdss of the J-FET 36 of the control circuit 11. In other words, a source-drain breakdown voltage Vdss is no more than the open circuit voltage Vocpd1 of the first photo receiving element 3 that is Vocpd1≧Vdss.

In this third embodiment, if the output voltage of the first photo receiving element 3 is changed, Voc is stable. This is because the Voc is dependent on the breakdown voltage Vdss of the J-FET 36. The J-FET 36 is larger ON-resistance and longer discharging time than the MOSFET.

In this third embodiment, the breakdown voltage of the J-FET of the control circuit is no more than the open circuit voltage of the photo receiving element. A stable output voltage can be obtained in the optical coupling device.

### Fourth Embodiment

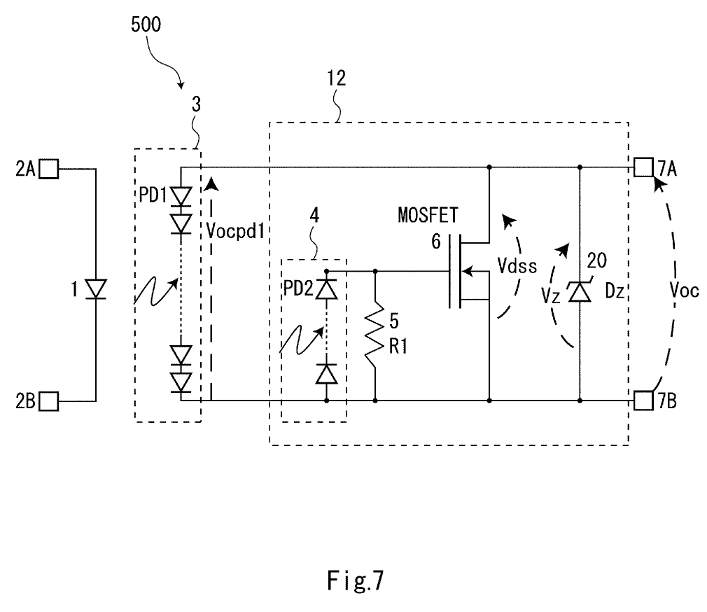

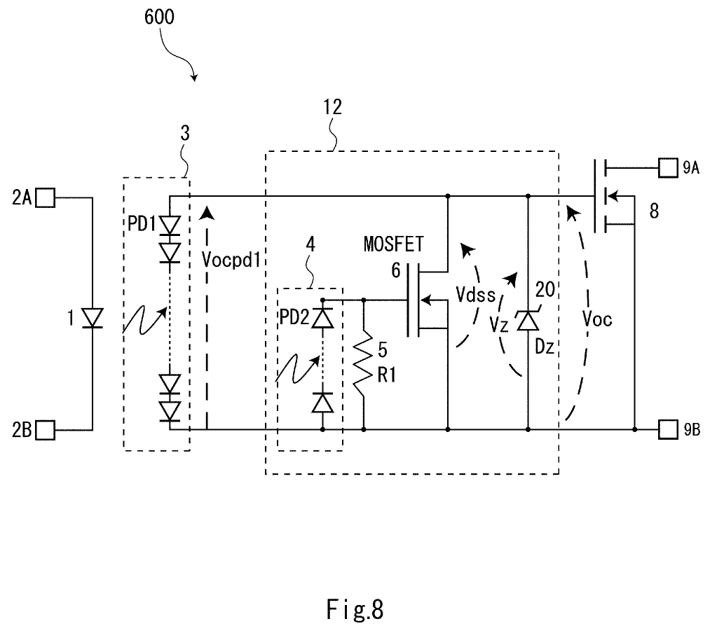

A fourth embodiment will be explained with reference to FIGS. 7 and 8.

An optical coupling device in accordance with a fourth embodiment of the present invention, with respect to each portion of this embodiment, the same or corresponding portions of the optical coupling device of the first, second or third embodiment shown in FIGS. 1-6 are designated by the same reference numerals, and its explanation of such portions is omitted.

FIG. 7 is a circuit diagram of a photo coupler as an optical coupling device in accordance with a fourth embodiment.

A difference between the photo coupler 100 and a photo coupler 500 as shown in FIG. 7 is in a control circuit 12.

In this fourth embodiment, the control circuit 12 has a constant voltage diode 20. The constant voltage diode 20 is connected parallel to the first photo receiving element 3 and the MOSFET 6. A cathode of the constant voltage diode 20 is connected to the output terminal 7A and an anode of the constant voltage diode 20 is connected to the output terminal 7B. the constant voltage diode 20 may be Zener diode or avalanche diode and so on.

An avalanche voltage Vz is no more than the open circuit voltage Vocpd1 of the first photo receiving element 3, and is no more than the breakdown voltage Vdss of the MOSFET 6 of control circuit 12.

The output voltage is decided by the avalanche voltage Vz. If the open circuit voltage Vocpd1 is changed by an ambient temperature or a receiving light, the Vz is output as Voc.

FIG. 8 is a circuit diagram of a photo relay as an optical coupling device in accordance with a fourth embodiment.

A difference between the photo relay 200 and the photo relay 600 as shown in FIG. 8 is in the control circuit 12.

The control circuit 12 has a constant voltage diode 20. The constant voltage diode 20 is connected parallel to the first photo receiving element 3 and the MOSFET 6. A cathode of the constant voltage diode 20 is connected to the output terminal 7A and an anode of the constant voltage diode 20 is connected to the output terminal 7B. The constant voltage diode 20 may be Zener diode or avalanche diode and so on.

An avalanche voltage Vz is no more than the open circuit voltage Vocpd1 of the first photo receiving element 3, and is no more than the breakdown voltage Vdss of the MOSFET 6 of control circuit 12.

The output voltage is decided by the avalanche voltage Vz. If the open circuit voltage Vocpd1 is changed by an ambient temperature or a receiving light, the Vz is output as Voc.

Other embodiments of the present invention will be apparent to those skilled in the art from consideration of the specification and practice of the invention disclosed herein. It is intended that the specification and example embodiments be considered as exemplary only, with a true scope and spirit of the invention being indicated by the following.

What is claimed is:

1. An optical coupling device, comprising:
a light emitting element configured to emit an optical signal;
a photo receiving element having serial connected photo diodes, the photo receiving element configured to receive the optical signal and generate an electrical signal; and
a control circuit having an active element, a source and a drain of the active element connected to both ends of the photo receiving element;
wherein a breakdown voltage of the control circuit is less than or equal to an open circuit voltage of the photo receiving element.

2. An optical coupling device of claim 1, further comprising an output element connected to the control circuit, the output element controlled by the control circuit.

3. An optical coupling device of claim 2, wherein the output element is a MOSFET and the output element is connected to a source and a gate of the MOSFET.

4. An optical coupling device of claim 1, wherein a number of the photodiode array connected serially is defined as n, the breakdown voltage of the control circuit is no more than 0.55×n (V).

5. An optical coupling device of claim 1, wherein the active element is one of a

6. An optical coupling device of claim 1, further comprising a constant voltage diode connected between both ends of the photo receiving element.

7. An optical coupling device of claim 3, further comprising a constant voltage diode connected between both ends of the photo receiving element.

8. An optical coupling device of claim 4, further comprising a constant voltage diode connected between both ends of the photo receiving element.

9. An optical coupling device of claim 2, wherein a number of the photodiode array connected serially is defined as n, the breakdown voltage of the control circuit is no more than 0.55×n (V).

10. An optical coupling device of claim 6, wherein a number of the photodiode array connected serially is defined as n, the breakdown voltage of the control circuit is no more than 0.55×n (V).

11. An optical coupling device, comprising:
a light emitting element configured to emit an optical signal;
a photo receiving element having serial connected photo diodes, the photo receiving element configured to receive the optical signal and generate an electrical signal; and
an active element connected to the photo receiving element, a source and a drain of the active element connected to both ends of the photo receiving element;
wherein a breakdown voltage of the active element is no more than an open circuit voltage of the photo receiving element.

12. An optical coupling device of claim 11, further comprising an output element connected to the control circuit, the output element controlled by the control circuit.

13. An optical coupling device of claim 11, wherein the output element is a MOSFET and the output element is connected to a source and a gate of the MOSFET.

14. An optical coupling device of claim 11, wherein a number of the photodiode array connected serially is defined as n, the breakdown voltage of the control circuit is no more than 0.55×n (V).

15. An optical coupling device of claim 11, wherein the active element is one of a MOSFET and J-FET.

16. An optical coupling device of claim 11, further comprising a constant voltage diode connected between both ends of the photo receiving element.

17. An optical coupling device of claim 13, further comprising a constant voltage diode connected between both ends of the photo receiving element.

18. An optical coupling device of claim 14, further comprising a constant voltage diode connected between both ends of the photo receiving element.

19. An optical coupling device of claim 12, wherein a number of the photodiode array connected serially is defined as n, the breakdown voltage of the control circuit is no more than 0.55×n (V).

20. An optical coupling device of claim 16, wherein a number of the photodiode array connected serially is defined as n, the breakdown voltage of the control circuit is no more than 0.55×n (V).
